(19) United States
(12) Patent Application Publication
(10) Pub. No.: US 2021/0156926 A1
(43) Pub. Date: May 27, 2021

(54) BATTERY CHARGE AND DISCHARGE CYCLING WITH PREDICTIVE LOAD AND AVAILABILITY CONTROL SYSTEM

(71) Applicant: Alan C. Knudson, Colorado City, AZ (US)

(72) Inventor: Alan C. Knudson, Colorado City, AZ (US)

(21) Appl. No.: 17/103,713

(22) Filed: Nov. 24, 2020

Related U.S. Application Data
(60) Provisional application No. 62/940,144, filed on Nov. 25, 2019.
(60) Provisional application No. 62/940,132, filed on Nov. 25, 2019.
(60) Provisional application No. 62/960,318, filed on Jan. 13, 2020.
(60) Provisional application No. 62/960,324, filed on Jan. 13, 2020.
(60) Provisional application No. 62/994,430, filed on Mar. 25, 2020.
(60) Provisional application No. 62/994,436, filed on Mar. 25, 2020.

(51) Int. Cl. G01R 31/392; G06F 1/3212; H02J 3/00; H02J 3/38; G01R 31/382

(52) U.S. Cl. CPC G01R 31/392; G06F 1/3212; H02J 3/003; H02J 2300/24; G01R 31/382; H02J 3/004; H02J 3/381

(57) ABSTRACT

A battery charge and discharge cycling with predictive load and availability control system has a server and a load control device. The server predicts usage and future solar capacity at the specific sites where the battery packs are in use. The batteries are cycled near the lower end of capacity (state of charge or SoC), which extends life. Further, the load control device can reduce a battery's SoC if the weather forecast is sunny. The load control device may turn on appliances in the home to use excess energy that is generated by the solar system.

### CROSS-REFERENCE TO RELATED APPLICATIONS

This application claims the benefit of U.S. Provisional Application Ser. No. 62/940,144, filed on Nov. 25, 2019; U.S. Provisional Application Ser. No. 62/940,132, filed on Nov. 25, 2019; U.S. Provisional Application Ser. No. 62/960,324, filed on Jan. 13, 2020; U.S. Provisional Application Ser. No. 62/960,318, filed on Jan. 13, 2020; U.S. Provisional Application Ser. No. 62/994,436, filed on Mar. 25, 2020; and U.S. Provisional Application Ser. No. 62/994,430, filed on Mar. 25, 2020; all of which are incorporated herein by reference.

### TECHNICAL FIELD

The present disclosure relates to a battery management and control system. More particularly, the present disclosure relates to a battery management and control system that improves the life span of a battery using discharge cycling and predictive load.

### BACKGROUND

Batteries for off grid homes are very expensive and short lived. Because of their expected 10-year life, it is difficult to finance them, leaving an individual paying for the entire cost of the battery upfront. However, if the battery's lifespan can be extended, the battery can be paid for over time and the battery may be used longer and more efficiently. Often, degradation of batteries, for off grid homes, comes from heat and state of charge, which leads to the battery's lifespan being shortened. In addition, it appears that off-grid customers only use 20-30% of their entire battery on most days. As a result, when it is sunny, the batteries are needed less, but they are fully-charged. Because most batteries are stored in an enclosed structure, the battery is full and hot at the same time.

Due to the lack of temperature control and regulation of the state of charge of the battery, the battery does not last as long as it should. There have been many attempts to curtail the degradation effects of heat and state of charge on batteries. Many have attempted to extend the life of a battery; however, many of those attempts have not been able to fix the degradation issues and prolong the life of the battery sufficiently. For example, the current art has been unable to 1) optimize state of charge for life extension by limiting charge to the battery based on the expected usage before the next charging period, 2) optimize cycle life by spreading discharge among multiple controllable battery units, 3) minimize resistance growth by programmatically avoiding phase changes in the battery due to suboptimal charge/discharge. The present disclosure seeks to solve these and other problems.

### SUMMARY OF EXAMPLE EMBODIMENTS

In one embodiment, a battery charge and discharge cycling with predictive load and availability control system (hereinafter referred to as “battery management system”) comprises a server (e.g., remote server, local server, computer, etc.) and a load control device. The server predicts usage and future solar capacity at the specific sites where the battery packs are located. For example, the server can predict 1) whether the sun will be out using received weather data, 2) power usage on weekdays vs. weekends, etc. The batteries are charged the minimal amount possible to cover the need. The batteries are cycled near the lower end of capacity (state of charge or SoC), which extends life. Further, the load control device can reduce a battery's SoC if the weather forecast is predicted to be sunny. The load control device may turn on appliances in the home to use excess energy that is generated by the solar panel system.

### BRIEF DESCRIPTION OF THE DRAWINGS

FIG. 1 illustrates a diagram of a battery system;

FIG. 2 illustrates a flowchart of a server of a battery system; and

FIG. 3 illustrates a flowchart of a least necessary SOC charging of a battery system.

### DETAILED DESCRIPTION OF EXAMPLE EMBODIMENTS

The following descriptions depict only example embodiments and are not to be considered limiting in scope. Any reference herein to “the invention” is not intended to restrict or limit the invention to exact features or steps of any one or more of the exemplary embodiments disclosed in the present specification. References to “one embodiment,” “an embodiment,” “various embodiments,” and the like, may indicate that the embodiment(s) so described may include a particular feature, structure, or characteristic, but not every embodiment necessarily includes the particular feature, structure, or characteristic. Further, repeated use of the phrase “in one embodiment,” or “in an embodiment,” do not necessarily refer to the same embodiment, although they may.

Reference to the drawings is done throughout the disclosure using various numbers. The numbers used are for the convenience of the drafter only and the absence of numbers in an apparent sequence should not be considered limiting and does not imply that additional parts of that particular embodiment exist. Numbering patterns from one embodiment to the other need not imply that each embodiment has similar parts, although it may.

Accordingly, the particular arrangements disclosed are meant to be illustrative only and not limiting as to the scope of the invention, which is to be given the full breadth of the appended claims and any and all equivalents thereof. Although specific terms are employed herein, they are used in a generic and descriptive sense only and not for purposes of limitation. Unless otherwise expressly defined herein, such terms are intended to be given their broad, ordinary, and customary meaning not inconsistent with that applicable in the relevant industry and without restriction to any specific embodiment hereinafter described. As used herein, the article “a” is intended to include one or more items. When used herein to join a list of items, the term “or” denotes at least one of the items, but does not exclude a plurality of items of the list. For exemplary methods or processes, the sequence and/or arrangement of steps described herein are illustrative and not restrictive.

It should be understood that the steps of any such processes or methods are not limited to being carried out in any particular sequence, arrangement, or with any particular graphics or interface. Indeed, the steps of the disclosed processes or methods generally may be carried out in various sequences and arrangements while still falling within the scope of the present invention.

The term “coupled” may mean that two or more elements are in direct physical contact. However, “coupled” may also mean that two or more elements are not in direct contact with each other, but yet still cooperate or interact with each other.

The terms “comprising,” “including,” “having,” and the like, as used with respect to embodiments, are synonymous, and are generally intended as “open” terms (e.g., the term “including” should be interpreted as “including, but not limited to,” the term “having” should be interpreted as “having at least,” the term “includes” should be interpreted as “includes, but is not limited to,” etc.).

As previously discussed, there is a need to extend the life and optimize battery usage and charge considering weather conditions, time of day, and expected usage.

While several attempts have been made at extending the life of the battery, the current art still fails to reach the full potential of a battery's life. As discussed herein, the lifespan may be increased by 1) optimizing the state of charge (“SoC”) based on predicted usage and solar generation data, 2) optimizing cycle life by spreading discharge among multiple controllable battery units, 3) minimizing resistance growth by programmatically avoiding phase changes in the battery due to suboptimal charge/discharge.

The battery management system and methods disclosed herein allow a battery to be optimized and have a prolonged life, avoiding costs for a user. Accurate weather data can lead to predictions of home usage and home solar generation as a function of temperature, cloud cover, and irradiance. Using these factors, the battery management system can determine the least necessary SoC for a battery. The least necessary SoC is defined as the lowest SoC a battery could have and still provide power to the home from one sunny day, or part of a day, to the next. Off-grid housing is designed differently than other solar systems. The solar systems are designed much larger to produce enough power on the cloudiest days of the year to power the home and fill up the battery system. This leads to having full batteries that degrade quickly.

If the weather can be predicted, then home energy usage and home energy generation can also be predicted, leading to a user being able to set the state of charge in the battery remotely. However, due to weather changing constantly, a server would need to be updated, for example, every few minutes or every hour. Accordingly, the weather is taken into account by the minute, hour, day, and week so that the battery will be empty when not needed, such as on sunny days, and at full charge during long periods of cloudy days. Regulating the SoC of the battery may increase the life of the battery up to four times the life of a typical battery. Typically, batteries for off grid homes are charged as soon as the sun come up. This means that the batteries would be full through the hottest parts of the day and not be discharged until the sun goes down, leading to rapid degradation of the battery. In order to reduce or prevent degradation, the battery management system disclosed herein reduces the charge based upon usage and weather data.

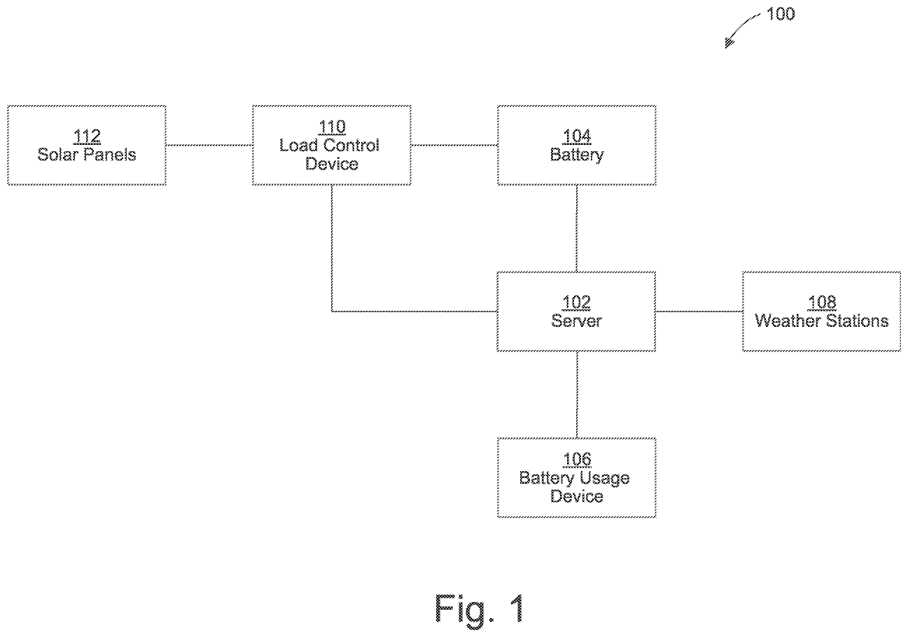

Referring to the diagram in FIG. 1, in one embodiment, the battery management system 100 comprises a processor, such as server 102 (e.g., remote server, local server, computer) or smart device or other processor, etc., batteries 104, a battery usage device 106 (e.g., home, trailer, equipment), weather stations 108 (which may be local or remote), a load control device 110, and solar panels 112. The server 102 predicts usage and future solar capacity at the home where the batteries 104 and solar panels 112 are in use. For example, the server 102 charges the batteries 104 by controlling the load control device 110 based upon on or more of: 1) how sunny it will be based upon obtained weather data, 2) the length of time from sunup to sundown, 3) the expected power usage (e.g., weekdays vs. weekends), among other factors. The batteries 104 are charged to a predetermined range, such as the minimal amount possible to cover the need (i.e., least necessary SoC). Cycling the batteries near the lower end of capacity (SoC of whole battery pack) extends the life of the battery, instead of keeping near full capacity when the future need is uncertain, which leads to battery degradation. In order for the server 102 to predict usage, the weather station 108 would ideally predict the forecast minute-to-minute. Extremely accurate micro-climate minute level forecasting methods, such as ClimaCell®, which give much higher accuracy estimates of weather and cloud cover by using an array of sensors from cars, cell towers, cell phones, security cameras etc., may be used to predict solar generation accurately enough to allow the battery management system 100 to switch from a first available energy to a last sufficient energy charging method. However, other types of weather stations/prediction methods may be used or incorporated.

Additionally, the load control device 110 can reduce a battery's SoC if the weather forecast is sunny. The load control device 110 may be in direct communication with the server 102. The load control device 110 may control power output by turning on appliances in the home, such as wells, fountains, A/C units, water heaters, lights, etc. to use excess energy that is generated by the solar system. In a typical system, this power would never be harvested, as the battery would be full, and the home loads powered by the solar panels. By predicting future needs, a potentially available energy estimate allows this power to pre-heat water, irrigate, run home appliances, and otherwise shift their loads to even further reduce battery degradation and maximize the self-consumption for large solar systems for off-grid homes 106.

The battery management system 100 is regulates battery charging to ensure that batteries do not reach their full charging capacity. For example, instead of charging the batteries 104 at first light (i.e., in the morning), the batteries 104 would remain un-charged throughout the majority of the day. The batteries 104 would then be charged just enough from the last few hours and minutes before the sun went down to leave the batteries 104 in the lowest possible SoC. It will be appreciated that the battery management system 100 is not limited to off-grid homes. The battery management system 100 may also be utilized for on-grid solar and battery backup systems in homes and businesses to minimize battery SoC while waiting for a power outage.

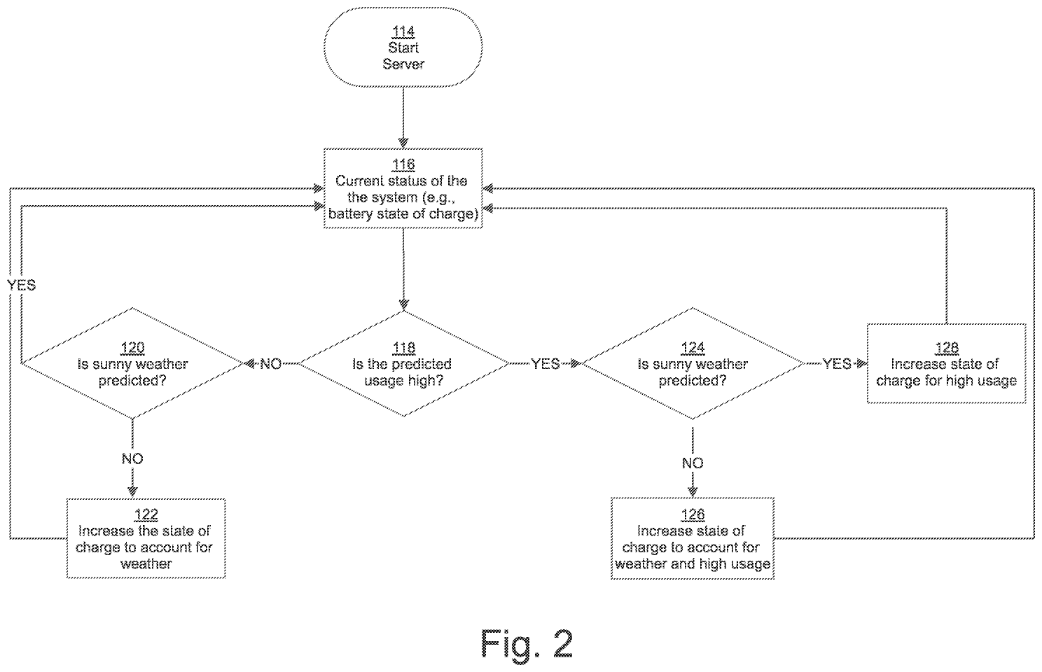

A method of using the battery management system 100 is illustrated in the flowchart of FIG. 2. At step 114, a server (e.g., remote server, local server, computer, etc.) is started and controls the battery management system 100. At step 116, the current status of the system, including the battery SoC, is determined. At step 118, the system determines whether the predicted usage is high based upon statistical use. If usage is not expected to be high, the system then determines the weather forecast at step 120. If sunny weather is predicted, the system loops. However, if sunny weather is not expected, then, at step 122, the state of charge needs to be increased to account for any changes in the weather. Referring back to step 118, if the predicted use is high, then, at step 124, weather is again predicted. If the weather is not sunny, then, at step 126, the system increases the state of charge to account for both weather and high usage. Alternatively, if the weather is predicted to be sunny, then, at step 128, the system will increase the state of charge only for the high usage. It will be appreciated that the predetermined ranges and thresholds for SoC will differ depending upon the number of batteries in the system, the capacity of those batteries, the size and location of the home, etc.

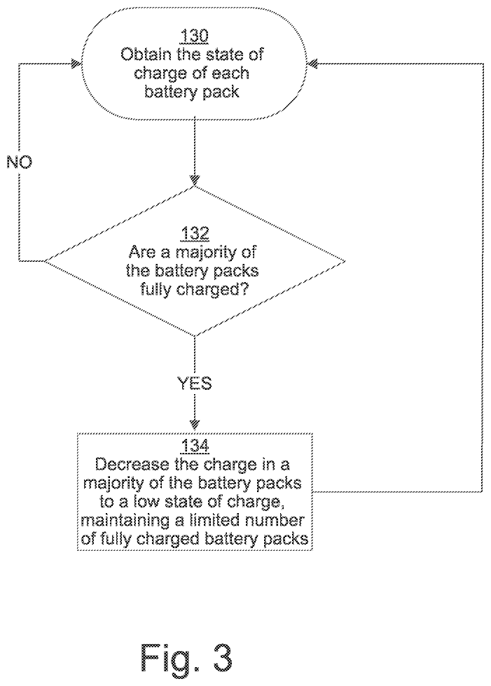

In addition, the battery management system 100 may be charged according to least necessary SoC charging. For example, a battery cell life, with many charge/discharge cycles with less depth of discharge (“DoD”) at a high SoC, is better than a battery that uses a full charge and discharge cycle. Thus, as illustrated in FIG. 3, the battery management system 100 can more fully charge the fewest number of battery packs within the battery management system 100 to accommodate the expected future demand. In particular, to start, at step 130, the state of charge of the battery packs is obtained. This may be accomplished using methods known in the art, such as open circuit voltage (OCV), closed circuit voltage (CCV), hydrometers, coulomb counting, impedance spectroscopy, etc. At step 132, the system determines if the battery packs are fully charged. If not, then the system returns back to step 130. If the answer is yes at step 132, the system proceeds to step 134 and allows a decrease in the charge in a majority of the battery packs to a low state of charge while maintaining a limited number of fully-charged battery packs. The remaining battery packs may be kept at a low SoC, which is the optimal storage condition for extending battery life.

In one embodiment, the low SoC for lithium batteries may be around 15% charge capacity. Then, a battery pack or a group of battery packs which are charged/discharged for each cycle (usually daily for solar), may be cycled through all battery packs such that the battery packs each have a lower amount of full charge/discharge cycles—increasing battery lifespan. In the event that usage is underestimated, the remaining battery packs held at a minimum charge for storage can also be further discharged (e.g., from 15% to 5% SoC). If there is no SoC in the battery packs, then power can be drawn from a grid connection or a backup generator which is typical in PV/wind off-grid systems. The combination of keeping the whole battery pack at lower SoC and then minimizing the number of full charge/discharge cycles of individual battery packs could potentially double the life of the battery pack system.

Further, the battery management system 100 may separate the batteries into multiple controllable units. This allows for many benefits, such as 1) multiple small batteries lasting much longer in partial DoD uses by optimally spreading the cycles between battery units, 2) switching between controllable units reduces heat degradation in the battery, and 3) long-term battery failure and end-of-life may be predicted, allowing for predictive maintenance or proactively spreading the cycles over the batteries for even degradation. It should be noted that the battery does not have to be larger capacity overall to be able to keep most battery cells at a low SoC. It should be noted that the overall capacity is sized for the worst-case scenario; for example, in the wintertime when days are short and not always sunny. The typical off-grid system keeps a battery pack fully charged as much as possible year-round. The battery management system 100 may be able to determine, using weather data, that the next two days are sunny then after that cloudy, and fully charge all cells for that cycle period.

In one embodiment, the battery management system microcycles batteries within resistance valleys as a method for decreasing resistance growth in a battery. By defining the low resistance/low degradation zones of optimal operation, the battery system can increase battery throughput of energy in Amp hours, while significantly reducing chemical aging and mechanical aging of the electrode, cathode, and anode. By measuring the common degradation factors in a battery, such as loss of cyclable lithium due to chemical aging, loss of active material in the negative electrode anode, and loss of active material in the positive electrode cathode resistance growth in the battery due to high C-rate and high temperatures, the battery can be protected from degradation.

When the degradation type is determined, the charge/discharge profiles can be adjusted to even out the degradation and maximize battery life. Batteries do not degrade evenly, and end of life can be affected due to increases of any of the identified degradation contributors. However, the battery management system herein is able to change the degradation of each type based on how the battery is cycled, charged, and discharged over time. When the degradation due to these factors is tracked, the battery management system can measure or estimate losses due to each degradation effect. The battery management system can then optimize the cycle life to evenly distribute the wear and tear in the battery for the longest possible life of the battery.

The battery management system 100 can be helpful by predicting anticipated energy generation, load requirements, and required SoC in the near and medium term to minimize chemical degradation of the battery. Specifically, the battery management system 100 may 1) optimize SoC for life extension by limiting charge to the battery based on the expected usage before the next charging period, 2) optimize cycle life by spreading discharge among multiple controllable battery units, and (3) minimize resistance growth by programmatically avoiding phase changes in the battery due to suboptimal charge/discharge. As a result, the battery management system overcomes issues in the prior art by extending battery life.

It will also be appreciated that systems and methods according to certain embodiments of the present disclosure may include, incorporate, or otherwise comprise properties or features (e.g., components, members, elements, parts, and/or portions) described in other embodiments. Accordingly, the various features of certain embodiments can be compatible with, combined with, included in, and/or incorporated into other embodiments of the present disclosure. Thus, disclosure of certain features relative to a specific embodiment of the present disclosure should not be construed as limiting application or inclusion of said features to the specific embodiment unless so stated. Rather, it will be appreciated that other embodiments can also include said features, members, elements, parts, and/or portions without necessarily departing from the scope of the present disclosure.

Moreover, unless a feature is described as requiring another feature in combination therewith, any feature herein may be combined with any other feature of a same or different embodiment disclosed herein. Furthermore, various well-known aspects of illustrative systems, methods, apparatus, and the like are not described herein in particular detail in order to avoid obscuring aspects of the example embodiments. Such aspects are, however, also contemplated herein.

Exemplary embodiments are described above. No element, act, or instruction used in this description should be construed as important, necessary, critical, or essential unless explicitly described as such. Although only a few of the exemplary embodiments have been described in detail herein, those skilled in the art will readily appreciate that many modifications are possible in these exemplary embodiments without materially departing from the novel teachings and advantages herein. Accordingly, all such modifications are intended to be included within the scope of this invention.

What is claimed is:

1. A battery management system for reducing battery degradation, the system comprising:
a server in communication with:
one or more batteries,
a load control device,
one or more weather stations, and
a battery usage device;
the server programmed to predict battery power usage and future solar capacity by:
i. predicting sunshine based on weather data obtained from the one or more weather stations, and
ii. determining expected power usage based on historical usage data;
upon predicting the power usage and solar capacity, the server controlling the state of charge of the one or more batteries via the load control device.

2. The system of claim 1, wherein the server controls the battery usage device to reduce the state of charge of the one or more batteries.

3. The system of claim 1, wherein upon predicting sunshine above a predetermined threshold and expected usage of power below a predetermined threshold, the server controls the load control device to maintain a state of charge below a predetermined threshold.

4. The system of claim 1, wherein upon predicting sunshine above a predetermined threshold and expected usage of power above a predetermined threshold, the server controls the load control device to increase a state of charge above a predetermined threshold.

5. The system of claim 1, wherein upon predicting sunshine below a predetermined threshold and expected usage of power above a predetermined threshold, the server controls the load control device to increase the state of charge above a predetermined threshold.

6. The system of claim 1, wherein the battery usage device comprises an appliance in a home.

7. The system of claim 1, wherein the state of charge is a least necessary state of charge.

8. The system of claim 1, wherein when expected power usage is predicted and weather data is obtained, the one or more batteries are charged to a predetermined range by one or more solar panels.

9. A battery management system for reducing battery degradation, the system comprising:
one or more batteries;
a load control device for controlling a charging status of the one or more batteries; and
a server for controlling the load control device, the server controlling the load control device based upon:
received weather data, and
predicted power usage based upon historical usage data.

10. The system of claim 9, wherein the server comprises a remote server.

11. The system of claim 9, further comprising a battery usage device, wherein the server controls the battery usage device to reduce the state of charge of the one or more batteries.

12. The system of claim 11, wherein the server reads the state of charge of the one or more batteries and, based upon received weather data and predicted power usage, decreases the state of charge in a majority of the batteries to below a predetermined threshold and maintains a limited number of batteries fully-charged.

13. A method of reducing battery degradation using a battery management system, the method comprising:
determining a battery's state of charge;
predicting power usage based upon statistical use;
predicting weather based upon received weather data;
increasing the state of charge of the battery to above a predetermined threshold when:
predicted power usage is high, or
overcast weather is predicted; and
decreasing the state of charge of the battery to below a predetermined threshold when:
predicted power usage is low, or
sunny weather is predicted.

14. The method of claim 13, wherein the weather is predicted using preprogrammed algorithms and weather data received from one or more weather stations.

15. The method of claim 13, wherein the state of charge of the battery is increased using solar panels.

16. The method of claim 13, wherein the state of charge of the battery is lowered using battery usage device.

17. The method of claim 16, wherein the battery usage device is a home appliance.

18. The method of claim 13, wherein in a system comprising multiple batteries, and upon determining the state of charge of each battery, decreasing the state of charge in a predetermined number of batteries to below a predetermined state of charge.

19. The method of claim 18, further comprising maintaining a predetermined number of batteries fully charged.

20. The method of claim 13, wherein the threshold for the low state of charge is a range of 5%-15% state of charge.
